(19) United States
(12) Patent Application Publication
(10) Pub. No.: US 2025/0046632 A1
(43) Pub. Date: Feb. 6, 2025

(54) HEAT TREATMENT APPARATUS AND METHOD OF OPERATING THEREOF

(71) Applicant: ROHM CO., LTD., Kyoto (JP)

(72) Inventors: Makoto TAKAMURA, Kyoto (JP); Keiju SATO, Kyoto (JP)

(73) Assignee: ROHM CO., LTD., Kyoto (JP)

(21) Appl. No.: 18/927,533

(22) Filed: Oct. 25, 2024

Related U.S. Application Data
(63) Continuation of application No. PCT/JP2023/016343, filed on Apr. 25, 2023.

(30) Foreign Application Priority Data
Apr. 27, 2022 (JP) 2022-073377

(51) Int. Cl. H01L 21/67; C23C 16/48; C30B 29/36; H01L 21/687

(52) U.S. Cl. CPC H01L 21/67115; C30B 29/36; H01L 21/68785; C23C 16/481

(57) ABSTRACT

A heat treatment apparatus includes a semiconductor substrate; a carbon susceptor on which the semiconductor substrate is placed; a first heating device; an optical system for condensing light output from the first heating device and irradiating the surface of the semiconductor substrate; and a second heating device which faces the semiconductor substrate across the carbon susceptor and is arranged at a distance from the carbon susceptor. The semiconductor substrate is heated to a first temperature by the second heating device; and the semiconductor substrate is heated to a second temperature higher than the first temperature by the first heating device with the optical system that condenses light and irradiates the semiconductor substrate.

### CROSS-REFERENCE TO RELATED APPLICATIONS

This is a continuation application (CA) of PCT Application No. PCT/JP2023/016343 filed on Apr. 25, 2023, which claims priority to Japan Patent Application No. P2022-073377 filed on Apr. 27, 2022 and is based upon and claims the benefit of priority from prior Japanese Patent Application No. P2022-073377 filed on Apr. 27, 2022 and PCT Application No. PCT/JP2023/016343 filed on Apr. 25, 2023; the entire contents of each of which are incorporated herein by reference.

### TECHNICAL FIELD

The disclosure relates to a heat treatment apparatus and a method of operating thereof.

### BACKGROUND

As a method of rapidly heating a semiconductor substrate, infrared lamp annealing is known. It is also known that graphene can be formed by performing a surface pyrolysis method on a surface of silicon carbide.

### BRIEF DESCRIPTION OF DRAWINGS

FIG. 1 is a top view of a heat treatment apparatus according to a first embodiment.

FIG. 2 is a cross-sectional view taken along line A1-A1 in FIG. 1.

FIG. 3A is a cross-sectional view showing a step of a method of operating the heat treatment apparatus according to the first embodiment.

FIG. 3B is a cross-sectional view showing a step following FIG. 3A.

FIG. 4 is an example of a temperature profile showing the relationship between temperature and time of the heat treatment apparatus according to the first embodiment.

FIG. 5 is a top view of a heat treatment apparatus according to a second embodiment.

FIG. 6 is a cross-sectional view along line A2-A2 in FIG. 5.

### DESCRIPTION OF EMBODIMENTS

Next, the present embodiment will be described with reference to the drawings. In the following description of the drawings, the same or similar parts are denoted by the same or similar symbols. However, it should be noted that the drawings are only schematic, and the relationship between the thickness and the plane dimension of each component is different from the actual one. Therefore, the specific thickness and dimension should be determined with reference to the following description. It is also a matter of course that the drawings include parts in which the relationship and ratio of the dimensions are different from each other.

Further, the embodiments shown below illustrate devices and methods for embodying technical ideas, and do not specify the material, shape, structure, arrangement, or the like of each component. Various modifications can be made to this embodiment within the scope of the claims.

### First Embodiment

A heat treatment apparatus 100 according to a first embodiment will be described with reference to the drawings.

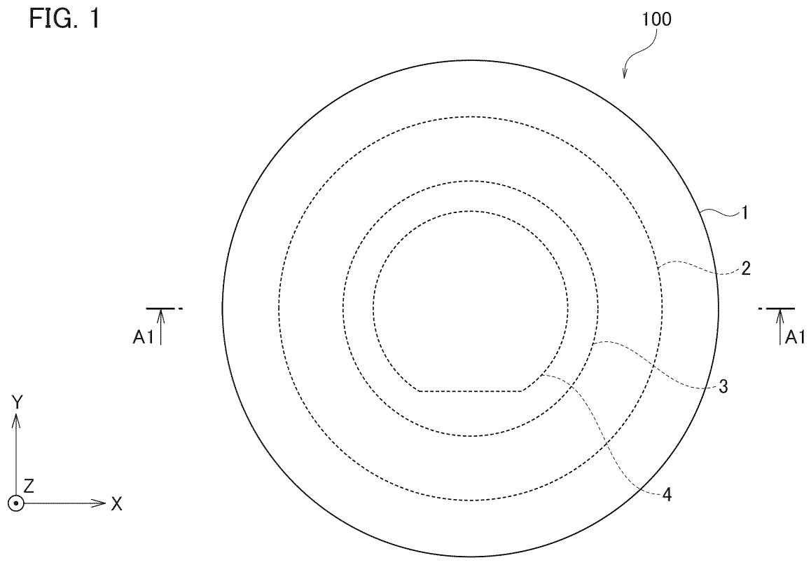

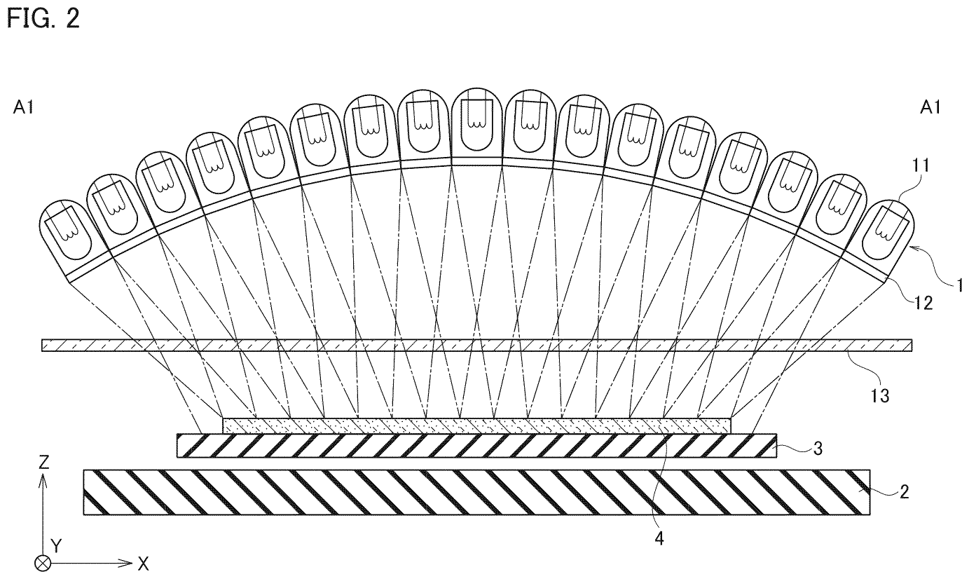

FIG. 1 is a top view of a heat treatment apparatus 100 according to a first embodiment. FIG. 2 is a cross-sectional view along line A1-A1 in FIG. 1. The device plane in the plan view shown in FIG. 1 is an XY plane, and a direction perpendicular to the XY plane is a Z axis. FIG. 2 is an XZ plane viewed from a Y direction. That is, a first direction parallel to the orientation flat plane of the semiconductor substrate 4 is called an X direction, a second direction intersecting the X direction is called the Y direction, and a third direction is called a Z direction. In the following description, the first direction is the X direction, the second direction is the Y direction, and the third direction is the Z direction.

As shown in FIG. 1, the heat treatment apparatus 100 according to the first embodiment includes a heating light source 1 as an example of the first heating apparatus 1, a resistance heating element 2 as an example of the second heating device 2, a carbon susceptor 3, and a semiconductor substrate 4. Although not shown, the heat treatment apparatus 100 is provided in a treatment chamber. Here, as shown in FIG. 2, at least two heating devices are provided in a treatment chamber of the heat treatment apparatus 100 in the vertical direction of the carbon susceptor 3 in a cross-sectional view along the XZ plane in the Y direction. The treatment chamber can be isolated from the outside air. The pressure in the treatment chamber may be adjusted to vacuum, or atmospheric pressure or higher by filling or flowing inert gas or the like. The heat treatment apparatus 100 may further includes a quartz glass 13 between the heating light source 1 and the semiconductor substrate 4. In the following description, the first heating device 1 will be referred to as the heating light source 1, and the second heating device 2 will be referred to as the resistance heating element 2.

The heating light source 1 includes a light source for heating. As shown in FIG. 1, the heating light source 1 is arranged in a circular shape in a plan view along the XY plane in the Z direction. The heating light source 1 is arranged so as to face the resistance heating element 2 across the semiconductor substrate 4 and the carbon susceptor 3. An area of the heating light source 1 is larger than an area of the semiconductor substrate 4 in a plan view along the XY plane in the Z direction.

As shown in FIG. 2, the heating light source 1 is arranged above the resistance heating element 2, the carbon susceptor 3, and the semiconductor substrate 4. Furthermore, the heating light source 1 is arranged in a hemispherical curve in a cross-sectional view along the XZ plane in the Y direction.

As shown in FIG. 2, the heating light source 1 has, for example, an assembly of infrared lamps 11. More specifically, halogen lamps 11 can be used for the infrared lamps 11, for example. In the following description, the infrared lamp 11 is also referred to as the halogen lamp 11.

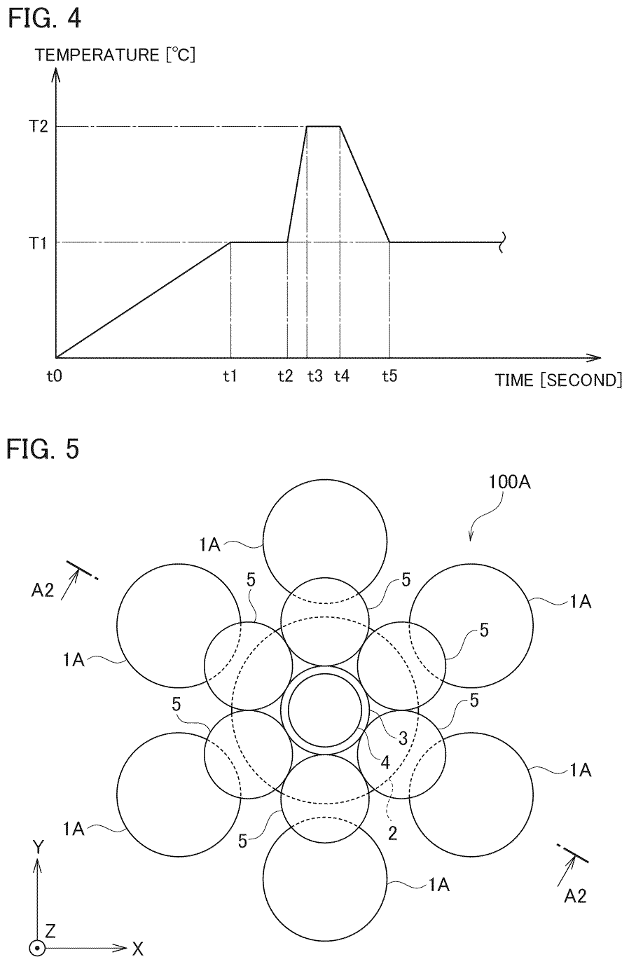

As shown in FIG. 2, the halogen lamp 11 has a condenser lens 12 as an example of an optical system. The condenser lens 12 is arranged above the semiconductor substrate 4. Specifically, infrared radiation emitted from the halogen lamp 11 may be incident on a collimator lens (not shown). The collimator lens collimates a divergent light emitted from the halogen lamp 11. The collimated infrared radiation is incident on the condenser lens 12. The incident infrared radiation is focused on the carbon susceptor 3 and the semiconductor substrate 4 by the condenser lens 12 on a plus side surface in the Z direction. That is, the carbon susceptor 3 and the semiconductor substrate 4 are absorbed by the plus side surface in the Z direction and heated by the thermal energy of the focused infrared radiation. In other words, the heating light source 1 can raise the temperature of the semiconductor substrate 4 to reach the temperature at which the silicon atoms (Si) contained in the semiconductor substrate 4 are sublimated by condensing the emitted infrared radiation. In the following description, the surface on the plus side in the Z direction is also referred to as a surface. The temperature at which the silicon atoms (Si) contained in the semiconductor substrate 4 are sublimated will be described, for example, with reference to FIG. 4.

The resistance heating element 2 includes a resistance for heating. The resistance heating element 2 is, for example, a heating element formed of carbon or the like in a resistance heating system. The carbon susceptor 3 and the semiconductor substrate 4 are absorbed by a surface on a minus side in the Z direction and heated by the radiation energy of the resistance heating element 2. Specifically, the resistance heating element 2 can, for example, preheat the carbon susceptor 3 and the semiconductor substrate 4 higher than or equal to 800° C., and lower than or equal to 1,200° C. in advance. The resistance heating element 2 can maintain a constantly heated state even when the carbon susceptor 3 on which the semiconductor substrate 4 is placed is not carried in. In addition, the resistance heating element 2 can carry in the carbon susceptor 3 on which the semiconductor substrate 4 is placed in a constantly heated state. Furthermore, in the constantly heated state, unnecessary gas adsorbed on the carbon susceptor 3 and the semiconductor substrate 4 is baked out, thereby reducing the influence on the subsequent process. In the following description, a surface on the minus side in the Z direction is also referred to as a back surface.

As shown in FIG. 1, the resistance heating element 2 is arranged in a circular shape in an XY plane view in the Z direction. The area of the resistance heating element 2 is larger than the area of the semiconductor substrate 4 in the XY plane view in the Z direction.

As shown in FIG. 2, the resistance heating element 2 is arranged below the heating light source 1, the carbon susceptor 3, and the semiconductor substrate 4. The resistance heating element 2 is arranged with a gap of greater than or equal to 0.15 mm, and less than or equal to 5.00 mm between the resistance heating element 2 and the carbon susceptor 3.

The carbon susceptor 3 is a substrate holder of the semiconductor substrate 4 that is heated by the heating light source 1 and the resistance heating element 2. The carbon susceptor 3 is arranged at a distance from the resistance heating element 2 as shown in FIG. 2. A thickness of the carbon susceptor is, for example, about 0.1 mm to 3.0 mm. By setting the thickness of the carbon susceptor to, for example, about 0.1 mm to 3.0 mm, both mechanical strength and heat capacity required for the carbon susceptor 3 can be reduced, and rapid temperature rise and temperature fall can be achieved.

As the semiconductor substrate 4, for example, single crystal silicon carbide (SIC) can be applied. In the following description, the semiconductor substrate 4 is also referred to as the SiC substrate 4.

The quartz glass 13 can prevent silicon atoms sublimated from the SiC substrate 4 from adhering to the condenser lens 12. Further, for example, by supplying argon gas to an entire inner surface of the chamber in a laminar flow manner in parallel with the surface of the SiC substrate 4 facing the quartz glass 13, the sublimated silicon atoms can be prevented from adhering to the surface of the quartz glass 13 facing the SiC substrate 4. That is, when the silicon atoms of the quartz glass 13 adhere to the condenser lens 12, transmittance of infrared rays emitted from the heating light source 1 decreases, and by suppressing the adhesion, the maintenance cycle of the heat treatment apparatus 100 can be extended, thereby improving productivity.

### Method of Operating Heat Treatment Apparatus

Next, a method of operating the heat treatment apparatus 100 according to the first embodiment will be described.

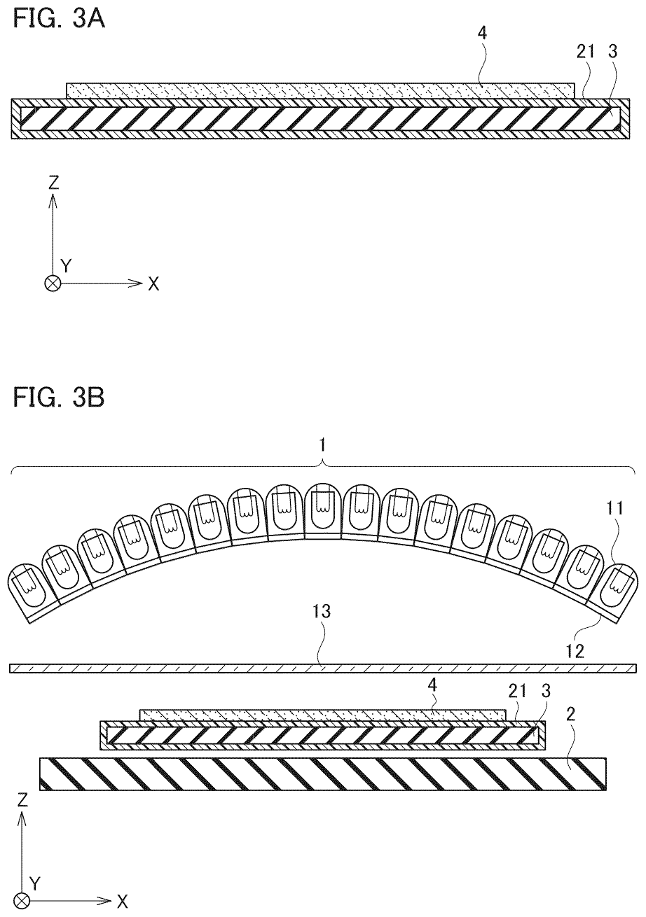

FIGS. 3A to 3B are cross-sectional views showing a step of the method of operating the heat treatment apparatus 100 according to the first embodiment. FIG. 4 is an example of a temperature profile showing the relationship between temperature and time in the heat treatment apparatus 100 according to the first embodiment.

First, as shown in FIG. 3A, the SiC substrate 4 is placed on the carbon susceptor 3. Specifically, the carbon susceptor 3 may be coated with, for example, a polycrystalline silicon carbide layer 21 formed in a high-temperature chemical vapor deposition (HT-CVD) method. By coating the carbon susceptor 3 with the polycrystalline silicon carbide layer 21, the amount of residual gas adsorbed on the carbon susceptor 3 can be reduced without lowering the absorption efficiency of radiant heat energy from the first heating device 1 and the second heating device 2. Furthermore, during heating, it is possible to suppress the influence of graphene formation due to the volatile gas, which is also called outgas, emitted from the carbon susceptor 3. That is, when there are impurities adhering to the carbon susceptor 3, the carbon susceptor 3 is heated by the first heating device 1 and the second heating device 2 to become a volatile gas. The volatile gas adhering to the surface of the SiC substrate 4 affects formation of graphene, so that the carbon susceptor 3 is coated with the polycrystalline silicon carbide layer 21. In addition, by preheating the carbon susceptor 3 to higher than or equal to 800° C., and lower than or equal to 1,200° C. using the radiant heat energy from the second heating device, the amount of residual gas adsorbed on the carbon susceptor 3 can be reduced by the baking-out effect.

Next, as shown in FIG. 3B, the heating light source 1 and the resistance heating element 2 are mounted in the processing chamber. Specifically, for example, the SiC substrate 4 is carried into the processing chamber while being placed on the carbon susceptor 3, and when the heating process is completed, the SiC substrate 4 is carried out while being placed on the carbon susceptor 3. Note that the temperatures of the carbon susceptor 3 and the SiC substrate 4 when carrying in may be room temperature. The temperatures of the carbon susceptor 3 and the SiC substrate 4 when carrying out may be higher than room temperature. That is, when carrying out, the SiC substrate 4 may be carried out before cooling to room temperature in the processing chamber because a temperature higher than room temperature does not affect the graphene after formation.

Next, the carbon susceptor 3 and the SiC substrate 4 are preheated to a first temperature T1 by the resistance heating element 2. Specifically, as shown in FIG. 4, for example, resistance heating element 2 is preheated to a first temperature T1 between timing t0 and timing t1. Here, the first temperature T1 is a temperature lower than a sublimation temperature of the silicon atoms contained in the SiC substrate 4. The first temperature T1 of, for example, higher than or equal to 800° C., and lower than or equal to 1,200° C. is applicable. When heated to 1,200° C. or lower, the surface of the SiC substrate 4 is not roughened by step bunching. Heating by the resistance heating element 2 may be maintained between the timing t1 and the timing t2 until the first temperature T1 is stabilized.

Next, the carbon susceptor 3 and the SiC substrate 4 are rapidly heated to a second temperature T2 higher than the first temperature T1 by the heating light source 1. Specifically, for example, as shown in FIG. 4, a rapid heating to the second temperature T2 higher than the first temperature T1 is performed between the timing t2 and the timing t3 by the heating light source 1. Here, the second temperature T2 is the sublimation temperature of the silicon atoms included in the SiC substrate 4. That is, it is a temperature at which one or more graphene layers can be formed on the SiC substrate 4. At the time of rapid heating, argon gas, which is an inert gas, may be introduced at the pressure in the heat treatment apparatus 100 to adjust the pressure to exceed the atmospheric pressure. By adjusting the pressure, the thermal conductivity due to thermal convection between the carbon susceptor 3 and the SiC substrate 4 can be improved, and the sublimation of silicon atoms on the surface of the SiC substrate 4 can be suppressed, and one or more graphene layers with low defects can be formed. The second temperature T2 of, for example, higher than or equal to 1,400° C., and less than or equal to 1,850° C. is applicable. The heating light source 1 is condensed by the condenser lens 12, so that a temperature higher than or equal to 1,400° C., and less than or equal to 1,850° C. can be achieved. In addition, the one or more graphene layers are formed in a short time by rapid in-plane uniform heating. As a result, formation of graphene layers is possible with the number of graphene layers being uniformly controlled while maintaining the smoothness of the SiC substrate 4. Note that a rate of rapid temperature rise up to the second temperature T2 may be, for example, more than or equal to 10° C., and less than 300° C. per second. Further, the heating light source 1 may maintain heating between the timing t3 and the timing t4 until the second temperature T2 is stabilized. The intensity of the radiant heat energy of the heating light source 1 and the resistance heating element 2 may be adjusted. By adjusting the intensity of the radiant heat energy, the temperature difference between the front surface and the back surface of the SiC substrate 4 can be reduced, and a warp due to heat can be suppressed. Moreover, the contact property between the carbon susceptor 3 and the SiC substrate 4 is improved due to a suppressed warp, so that the temperature distribution on the surface of the SiC substrate 4 is made uniform.

Next, the heating of the heating light source 1 is interrupted, and the temperatures of the carbon susceptor 3 and the SiC substrate 4 are rapidly lowered to the first temperature T1. Specifically, for example, as shown in FIG. 4, the heating light source 1 interrupts the heating between the timing t4 and the timing t5, and the temperature is rapidly lowered by efficiently radiating thermal energy from the carbon susceptor 3 and the SiC substrate 4. A rate of rapid temperature fall from the second temperature T2 to the first temperature may be, for example, more than or equal to 2° C., and less than 10° C. per second.

One or more graphene layers can be formed on the SiC substrate 4 by the method of operation of the heat treatment apparatus according to the first embodiment described above.

As described above, according to the first embodiment, the SiC substrate 4 is heated to the first temperature T1 by the resistive heating element 2. The light output from the heating light source 1 is condensed and the surface of the SiC substrate 4 is irradiated by the heating light source using an optical system, so that the SiC substrate 4 is heated to the second temperature T2 higher than the first temperature T1. As a result, one or more graphene layers excellent in flatness and layer number controllability can be formed.

Further, according to the first embodiment, the SiC substrate 4 can be rapidly heated to a second temperature T2 higher than the first temperature T1 by arranging the heating light source 1 above the SiC substrate 4 and irradiating the condensed light by the condenser lens 12.

### Second Embodiment

Next, the heat treatment apparatus 100A according to a second embodiment will be described with reference to the drawings.

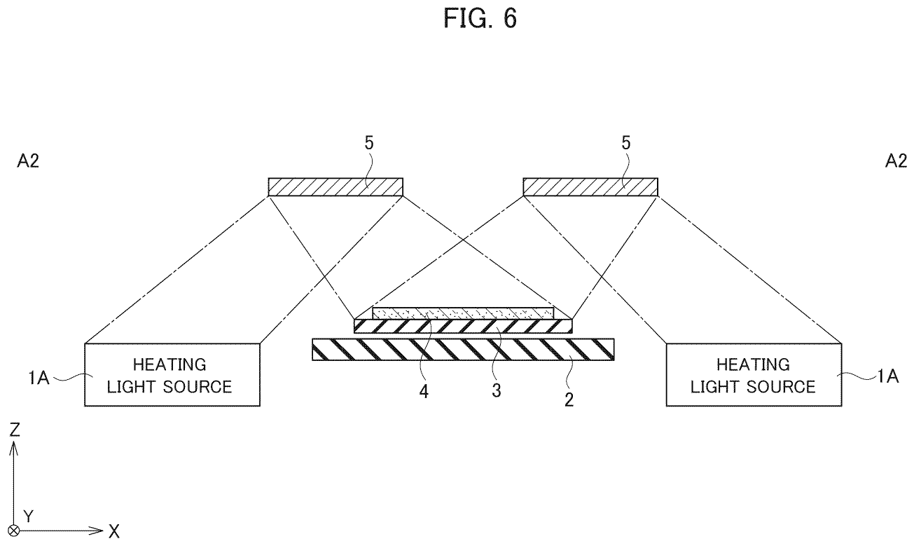

FIG. 5 is a top view of the heat treatment apparatus 100A according to the second embodiment. FIG. 6 is a sectional view along line A2-A2 in FIG. 5.

As shown in FIGS. 5 and 6, the heat treatment apparatus 100A according to the second embodiment includes a heating light source 1A instead of the heating light source 1 in the heat treatment apparatus 100 according to the first embodiment. The heating light source 1A is another example of the first heating device. The heat treatment apparatus 100A according to the second embodiment further includes a reflecting mirror 5 as another example of the optical system. Other configurations, operation methods, and effects are the same as those of the first embodiment. Although not shown, quartz glass may be further provided between the reflecting mirror 5 and the SiC substrate 4 as in the first embodiment.

The heating light source 1A includes a light source for heating. As shown in FIG. 5, the heating light source 1A is arranged in a circular shape in the XY plane view in the Z direction. A plurality of the heating light sources 1A are arranged at a distance across the resistance heating element 2 in the XY plane view in the Z direction. The area of the heating light source 1A is larger than the area of the semiconductor substrate 4 in the XY plane view in the Z direction.

As shown in FIG. 6, the heating light source 1A is arranged below the resistance heating element 2, the carbon susceptor 3, and the semiconductor substrate 4. Although not shown, the heating light source 1A is arranged in a hemispherical curve in a sectional view along the XZ plane in the Y direction, similar to the heating light source 1 according to the first embodiment.

Although not shown, the heating light source 1A has, for example, an assembly of the infrared lamps 11, similar to the heating light source 1. Specifically, halogen lamps 11 can be used for the infrared lamps 11, for example. As in the first embodiment, the halogen lamps 11 may include a condenser lens 12 as an example of an optical system. That is, the infrared radiation emitted from the heating light source 1A may be condensed and irradiated to the reflecting mirror 5. The condenser lens 12 may be arranged below the carbon susceptor 3 and the SiC substrate 4.

As shown in FIG. 6, the heating light source 1A emits infrared radiation and irradiates the reflecting mirror 5. That is, the infrared radiation is condensed on the surfaces of the carbon susceptor 3 and the SiC substrate 4 by irradiating the reflecting mirror 5 from the heating light sources 1A. In other words, the carbon susceptor 3 and the SiC substrate 4 are absorbed by the surface on the plus side in Z direction and heated by the thermal energy of the condensed infrared radiation. The heating light source 1A can reach a temperature to sublimate the silicon atoms contained in the SiC substrate 4 by condensing the emitted radiation and heating the SiC substrate 4.

The reflecting mirror 5 is arranged above the SiC substrate 4. The reflecting mirror 5 reflects the infrared radiation emitted from the plurality of heating light sources 1A and irradiates the surfaces of the carbon susceptor 3 and the SiC substrate 4.

### OTHER EMBODIMENTS

Although an embodiment has been described as above, the description and drawings forming a part of the disclosure are illustrative and should not be understood as limiting. Various alternative embodiments, examples and operating techniques will become apparent to those skilled in the art from this disclosure. Thus, this embodiment includes various embodiments and others which are not described herein.

The present disclosure includes configurations related to the following appended notes.

### Appended Note 1

A heat treatment apparatus including:
a semiconductor substrate 4; a carbon susceptor 3 on which the semiconductor substrate 4 is placed; a first heating device 1, 1A; an optical system 12, 5 for condensing light output from the first heating device 1 and irradiating a surface of the semiconductor substrate 4; and a second heating device 2 which faces the semiconductor substrate 4 across the carbon susceptor 3 and is arranged at a distance from the carbon susceptor 3. The semiconductor substrate 4 is heated to a first temperature T1 by the second heating device 2; and the semiconductor substrate 4 is heated to a second temperature T2 higher than the first temperature T1 by the first heating device 1, 1A with the optical system 12 that condenses light and irradiates the semiconductor substrate. The first heating light sources 1, 1A condense light with the optical systems 12, 5, so that the one or more graphene layers are formed in a short time by rapid in-plane uniform heating. As a result, formation of graphene layers is possible with the number of graphene layers being uniformly controlled while maintaining the smoothness of the semiconductor substrate 4.

### Appended Note 2

The heat treatment apparatus according to appended note 1, in which the optical system 12 is arranged above the semiconductor substrate 4.

### Appended Note 3

The heat treatment apparatus according to appended note 1, in which the optical system 12 is arranged below the semiconductor substrate 4.

### Appended Note 4

The heat treatment apparatus according to any one of appended notes 1 to 3, in which the first temperature T1 is a temperature lower than a sublimation temperature of silicon atoms contained in the semiconductor substrate 4; and the second temperature T2 is a sublimation temperature of silicon atoms contained in the semiconductor substrate 4.

### Appended Note 5

The heat treatment apparatus according to any one of appended notes 1 to 4, in which the first heating device includes a heating light source 1, 1A, and the second heating device includes a resistance heating element 2.

### Appended Note 6

The heat treatment apparatus according to any one of appended notes 1 to 5, in which a rate of rapid temperature rise of the heating light source 1 and 1A is more than or equal to 10° C., and less than 300° C. per second.

### Appended Note 7

The heat treatment apparatus according to any one of appended notes 1 to 5, in which a rate of rapid temperature fall of the heating light source 1 and 1A is more than or equal to 2° C., and less than 10° C. per second.

### Appended Note 8

The heat treatment apparatus according to any one of appended notes 1 to 7, in which an area of the first heating device 1 and 1A is larger than an area of the surface of the semiconductor substrate 4.

### Appended Note 9

The heat treatment apparatus according to any one of appended notes 1 to 8, further including a quartz glass 13 between the optical systems 12, 5 and the semiconductor substrate 4. The quartz glass 13 can prevent silicon atoms sublimated from the semiconductor substrate 4 from adhering to the optical system 12.

### Appended Note 10

The heat treatment apparatus according to any one of appended notes 1 to 9, in which a thickness of the carbon susceptor 3 is between 0.1 mm and 3.0 mm.

### Appended Note 11

The heat treatment apparatus according to any one of appended notes 1 to 10, further including a polycrystalline silicon carbide layer 21 with which a surface of the carbon susceptor 3 is coated. By coating the carbon susceptor 3 with the polycrystalline silicon carbide layer 21, the amount of residual gas adsorbed on the carbon susceptor 3 can be reduced without lowering the absorption efficiency of radiant heat energy from the first heating device 1 and the second heating device 2. Furthermore, during heating, it is possible to suppress the influence of graphene formation due to the volatile gas, which is also called outgas, emitted from the carbon susceptor 3.

### Appended Note 12

The heat treatment apparatus according to any one of appended notes 1 to 11, in which the optical system includes a condenser lens 12.

### Appended Note 13

The heat treatment apparatus according to any one of appended notes 1 to 12, in which the first heating device 1 is arranged above the second heating device 2, the carbon susceptor 3, and the semiconductor substrate 4.

### Appended Note 14

The heat treatment apparatus according to any one of the appended notes 1 to 13, in which the first heating device 1 and the second heating device 2 are arranged at a distance from each other across the carbon susceptor 3.

### Appended Note 15

The heat treatment apparatus according to any one of appended notes 1 to 12, in which the optical system includes a reflecting mirror 5 that reflects light output from the first heating device 1A and irradiates the surface of the semiconductor substrate 4.

### Appended Note 16

The heat treatment apparatus according to any one of appended notes 1 to 12, and 15, in which the first heating device 1A is arranged below the carbon susceptor 3 and the semiconductor substrate 4.

### Appended Note 17

The heat treatment apparatus according to any one of appended notes 1 to 12, 15 and 16, in which a plurality of the first heating devices 1A are arranged at a distance across the second heating device 2 in a plan view.

### Appended Note 18

A method of operating a heat treatment apparatus, including: placing a semiconductor substrate 4 on a carbon susceptor 3; heating the semiconductor substrate 4 to a first temperature T1 by a second heating device 2; condensing the light output from a first heating device 1, 1A and irradiating the surface of the semiconductor substrate 4 by the first heating device 1, 1A using an optical system 12, 5; heating the semiconductor substrate 4 to a second temperature T2 higher than the first temperature T1; and forming one or more graphene layers on the semiconductor substrate 4. The first heating light sources 1, 1A condense light with the optical systems 12, 5, so that the one or more graphene layers are formed in a short time by rapid in-plane uniform heating. As a result, formation of graphene layers is possible with the number of graphene layers being uniformly controlled while maintaining the smoothness of the semiconductor substrate 4.

### Appended Note 19

The method of operating a heat treatment apparatus according to appended note 18, in which the semiconductor substrate 4 includes a single crystal silicon carbide substrate; and a surface of the single crystal silicon carbide substrate is a (0001) plane.

### Appended Note 20

The method of operating a heat treatment apparatus according to appended note 18 or 19, in which pressure in the heat treatment apparatus is adjusted to exceed atmospheric pressure.

1. A heat treatment apparatus comprising:
a semiconductor substrate;
a carbon susceptor on which the semiconductor substrate is placed;
a first heating device;
an optical system for condensing light output from the first heating device and irradiating a surface of the semiconductor substrate; and
a second heating device which faces the semiconductor substrate across the carbon susceptor and is arranged at a distance from the carbon susceptor;
wherein:
the semiconductor substrate is heated to a first temperature by the second heating device; and
the semiconductor substrate is heated to a second temperature higher than the first temperature by the first heating device with the optical system that condenses light and irradiates the semiconductor substrate.

2. The heat treatment apparatus according to claim 1, wherein the optical system is arranged above the semiconductor substrate.

3. The heat treatment apparatus according to claim 1, wherein the optical system is arranged below the semiconductor substrate.

4. The heat treatment apparatus according to claim 1, wherein:
the first temperature is a temperature lower than a sublimation temperature of silicon atoms contained in the semiconductor substrate; and
the second temperature is a sublimation temperature of silicon atoms contained in the semiconductor substrate.

5. The heat treatment apparatus according to claim 1, wherein:
the first heating device comprises a light source for heating; and
the second heating device comprises a resistance heating element.

6. The heat treatment apparatus according to claim 1, wherein a rate of rapid temperature rise of the light source for heating is more than or equal to 10° C., and less than 300° C. per second.

7. The heat treatment apparatus according to claim 1, wherein a rate of rapid temperature fall of the heating light source is more than or equal to 2° C., and less than 10° C. per second.

8. The heat treatment apparatus according to claim 1, wherein an area of the first heating device is larger than an area of the surface of the semiconductor substrate.

9. The heat treatment apparatus according to claim 1, further comprising quartz glass between the optical system and the semiconductor substrate.

10. The heat treatment apparatus according to claim 1, wherein a thickness of the carbon susceptor is between 0.1 mm and 3.0 mm.

11. The heat treatment apparatus according to claim 1, further comprising a polycrystalline silicon carbide layer with which a surface of the carbon susceptor is coated.

12. The heat treatment apparatus according to claim 1, wherein the optical system comprises a condenser lens.

13. The heat treatment apparatus according to claim 1, wherein the first heating device is arranged above the second heating device, the carbon susceptor, and the semiconductor substrate.

14. The heat treatment apparatus according to claim 1, wherein the first heating device and the second heating device are arranged at a distance from each other across the carbon susceptor.

15. The heat treatment apparatus according to claim 1, wherein the optical system comprises a reflecting mirror that reflects light output from the first heating device and irradiates the surface of the semiconductor substrate.

16. The heat treatment apparatus according to claim 1, wherein the first heating device is arranged below the carbon susceptor and the semiconductor substrate.

17. The heat treatment apparatus according to claim 1, wherein a plurality of the first heating devices are arranged at a distance across the second heating device in a plan view.

18. A method of operating a heat treatment apparatus, comprising:
placing a semiconductor substrate on a carbon susceptor;
heating the semiconductor substrate to a first temperature by a second heating device;
condensing the light output from a first heating device and irradiating the surface of the semiconductor substrate by the first heating device using an optical system;
heating the semiconductor substrate to a second temperature higher than the first temperature; and
forming one or more graphene layers on the semiconductor substrate.

19. The method of operating a heat treatment apparatus according to claim 18, wherein:
the semiconductor substrate comprises a single crystal silicon carbide substrate; and
a surface of the single crystal silicon carbide substrate is a (0001) plane.

20. The method of operating a heat treatment apparatus according to claim 18, wherein pressure in the heat treatment apparatus is adjusted to exceed atmospheric pressure.
